(19) United States
(12) Patent Application Publication
(10) Pub. No.: US 2026/0001805 A1
(43) Pub. Date: Jan. 1, 2026

(54) Hybrid Panel with an Edge Coated Glass Panel

(71) Applicant: Intel Corporation, Santa Clara, CA (US)

(72) Inventors: Yi LI, Chandler, AZ (US); Praveen SREERAMAGIRI, Gilbert, AZ (US); Ibrahim El KHATIB, Chandler, AZ (US); Robin McREE, Chandler, AZ (US); Jesse JONES, Chandler, AZ (US); Srinivas PIETAMBARAM, Chandler, AZ (US); Gang DUAN, Chandler, AZ (US)

(21) Appl. No.: 18/755,718

(22) Filed: Jun. 27, 2024

(51) Int. Cl. C03C 17/00; C03C 17/32; H01L 23/15

(52) U.S. Cl. CPC C03C 17/002; C03C 17/326; C03C 2217/78; C03C 2218/32; H01L 23/15

(57) ABSTRACT

According to the various aspects, a hybrid panel assembly includes an edge coated glass panel that is formed using a glass panel having peripheral edges and an adhesive coating layer deposited on the peripheral edges of the glass panel. The edge coated glass panel is a subcomponent for the construction of the hybrid panel assembly. A frame is provided to surround the edge coated glass panel and the adhesive coating layer bonds the frame to the glass panel to complete the construction of the hybrid panel assembly. In an aspect, the adhesive coating layer may be deposited by a coating roller and cured by a UV source.

### BACKGROUND

For integrated circuit design and fabrication, the need to improve performance and lower costs are constant challenges. The continuing trend towards miniaturization, i.e., a reduction in the form factor for a printed circuit board with a semiconductor package and various other components, may lead to lower material costs, as well as improved performance with more compact designs. Further cost savings may potentially be realized by building dies on semiconductor panels rather than semiconductor wafers.

By using a rectangular panel as a substrate, panel-level fan-out technology offers the potential for lower production cost due to a higher area utilization ratio of the carrier and better economical manufacturing, especially for large packages. Presently, there are efforts to develop panel-level packaging technology that will follow a roadmap that will lead to increasingly larger panels, e.g., 610 mm by 650 mm panels and larger. However, there may be physical limits in panel-level packaging that may prevent the use of larger panels, such as warpage, and it has become clear that the manufacturing of these types of packages requires the use of a rigid core material, such as glass.

However, the brittle nature of glass may result in handling challenges during the course of a substrate flow process. While small chips and defects may not immediately degrade a glass core, the presence of edge chipping in the glass core caused by contact between a corner/edge of the glass core and a processing tool may lead to damage to the whole panel from stress that accumulates as the build-up layers with different coefficient of thermal expansion (CTE) are stacked on top of the glass core. The cracks initiated from small defects may propagate through the glass core resulting in “SeWaRe” (i.e. glass core splitting). Such glass core splitting may specifically arise during end-of-line singulation and other semiconductor processing steps. Accordingly, various methods for edge protection have been used to help glass core substrate panels avoid being damaged during the manufacturing process flow.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIGS. 1 and 1A show an exemplary representation of a hybrid panel according to an aspect of the present disclosure;

FIGS. 2A, 2B, and 2C show an exemplary representation of forming an edge coated glass panel according to an aspect of the present disclosure;

FIGS. 3A, 3B, and 3C show exemplary representation of forming a hybrid panel using an edge coated glass panel according to an aspect of the present disclosure; and

FIG. 4 shows a simplified flow diagram for an exemplary method for constructing a hybrid panel according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

According to the present disclosure, a hybrid panel assembly, and the manufacturing process therefore, is able to realize automated construction operations with less human involvement and errors. In an aspect, the edges of a glass panel may coated with selected coating materials (e.g., low CTE and high modulus materials) to provide strength and resilience in bonding the glass sub-panel with a copper clad laminate (CCL) frame. An applicator, e.g., a coating roller, provides a dispensing method that allows a larger viscosity window, as compared with needle dispensing, aerosol jetting, and other methods. In another aspect, a robot arm may be used to pick and place the edge coated glass panel and/or the CCL frame during the manufacturing process for the hybrid panel assembly. The coating material may be UV-cured or thermally cured to form a permanent bridge between the glass panel and the CCL frame.

The present disclosure is directed to a hybrid panel assembly having an edge coated glass panel that includes a glass panel with peripheral edges and an adhesive coating layer deposited on the peripheral edges of the glass panel. The edge coated glass panel is a subcomponent for the construction of the hybrid panel assembly and may be built in advance and stored until ready to be used.

The present disclosure is also directed to a method that provides a glass panel having peripheral edges and applies an adhesive coating layer on the peripheral edges of the glass panel, using an applicator, to form an edge coated glass panel. The edge coated glass panel may be built in advance as a subcomponent for the construction of a hybrid panel assembly.

The present disclosure is further directed to a hybrid panel assembly that includes an edge coated glass panel that is formed using a glass panel having peripheral edges and an adhesive coating layer deposited on the peripheral edges of the glass panel. The edge coated glass panel is a subcomponent for the construction of the hybrid panel assembly. A frame is provided to surround the edge coated glass panel and the adhesive coating layer bonds the frame to the glass panel to complete the construction of the hybrid panel assembly.

The technical advantages of the present disclosure include, but are not limited to:
(i) providing improved hybrid panel using an edge coated glass panel as a subcomponent;
(ii) providing ambient temperature processes that do not require high temperatures to be used, for example, in the coating/depositing and curing of the adhesive coating layer; and
(iii) providing reduced cost and higher mechanical accuracy using automated equipment including a robotic tool for moving subcomponents and an applicator for depositing the adhesive coating layer.

To more readily understand and put into practical effect the present hybrid panel assembly and methods, which may provide improved semiconductor device production, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

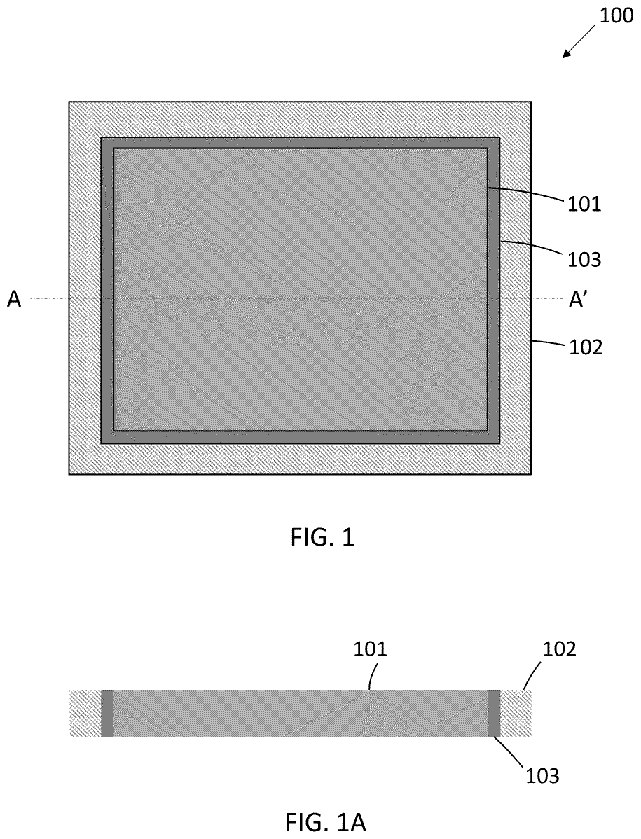

FIGS. 1 and 1A show an exemplary representation of a hybrid panel 100 according to an aspect of the present disclosure. The hybrid panel 100 is an assembly formed by a glass panel 101 and copper clad laminate (CCL) frame 102 that is bonded together by an adhesive layer 103. The CCL frame may be cut to size from a commercially available CCL panel. The hybrid panel 100 provides a unitary structure that may be transported and placed in semiconductor processing tools for the build-up process steps used to construct semiconductor packages.

In an aspect, a present hybrid panel may have a glass panel that has a size (i.e., width and length) in the range of approximately 480×482 mm to 500×505 mm and a thickness in the range of approximately 100 μm to 1 mm. In another aspect, the hybrid panel assembly of the glass panel and the CCL frame have a size of approximately 510×515 mm, which may be suitable for most semiconductor packaging tool designs.

As shown in FIG. 1A, a cross-section view of the hybrid panel 100 is provided along section line A-A′. In this view, the adhesive layer 103 is between the glass panel 101 and the CCL frame 102 and may have a thickness in a range of approximately 100 μm to 1 mm that is approximately equal to the thicknesses of the glass panel 101 and CCL frame 102.

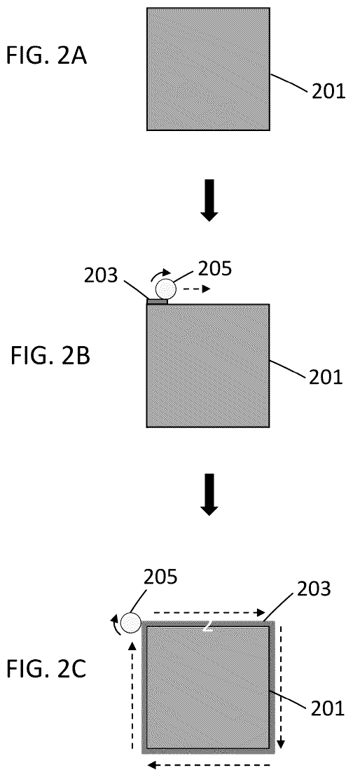

FIGS. 2A, 2B, and 2C show an exemplary representation of forming an edge coated glass panel according to an aspect of the present disclosure. As shown in FIG. 2A, a glass panel 201 is provided. As shown in FIG. 2B, an applicator (e.g., a coating roller, a sprayer, etc.) is used to apply an adhesive coating layer 203 on a peripheral edge or the glass panel 201. In an aspect, the adhesive coating layer 203 may be any epoxy-based resin/adhesive, which may include a filler material, e.g., ceramics or metal particles, to strengthen the bonding. The applicator may apply the adhesive coating layer that has a wider range of viscosity, e.g., 240 to 2700 cps).

In another aspect, the coefficient of thermal expansion (CTE) of an adhesive coating layer may be “tuned” by adding different weight percentages of fillers and it is preferred that the CTE of adhesive coating layer 203 be approximately the same or similar to a CTE for a glass panel and a CTE for a CCL frame being used to construct a hybrid panel.

As shown in FIG. 2C, the adhesive coating layer 203 is completely deposited on the peripheral edges of the glass panel 201. The depositing of an adhesive coating layer on the periphery edges of a glass panel may be performed by an automated process and at ambient or room temperature.

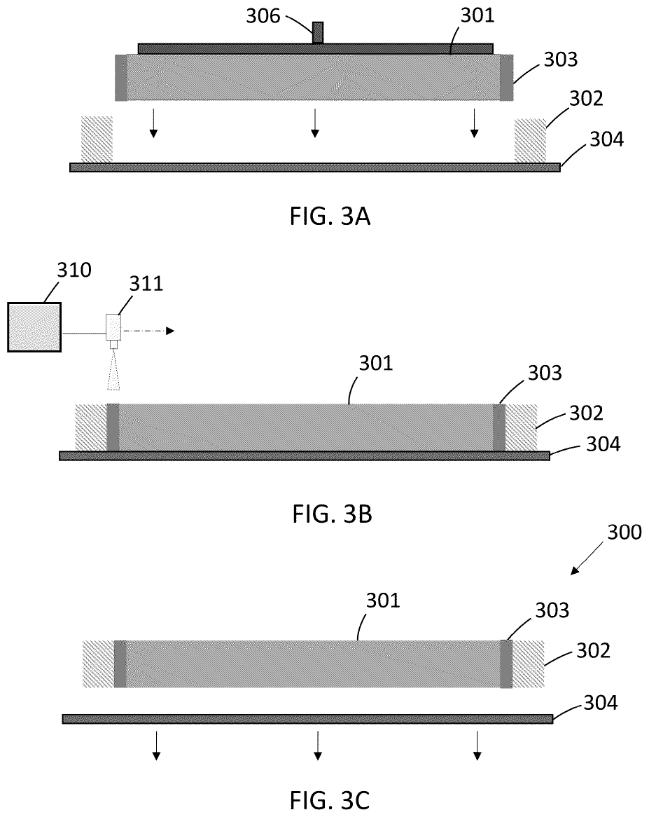

FIGS. 3A, 3B, and 3C show the exemplary formation of a hybrid panel 300 using an edge coated glass panel 301 according to an aspect of the present disclosure. As shown in FIG. 3A, an edge coated glass panel 301 having an adhesive coating layer 303 may be positioned (e.g., by an automated process using a robotic arm 306 or manually) within a frame 302 that has a support film 304. The frame 302 may provide a 2 to 3 mm tolerance for positioning edge coated glass panel 301. In this aspect, the frame 302 may be constructed from a copper cladded laminate (CCL) panel, which is commercially available. As shown in FIG. 3B, the edge coated glass panel 301 may be positioned on the support film 304 and the adhesive coating layer 303, which may be proximal to or in contact with the frame 302. In an aspect, the adhesive coating layer 303 may be cured using a UV-source 311 that is coupled to a processor 310 that controls the polymerization pattern and rate. Alternatively, the adhesive coating layer may be cured by a conventional thermal process. After the adhesive coating layer 303 is cured, the support film 304 may be removed as shown in FIG. 3C.

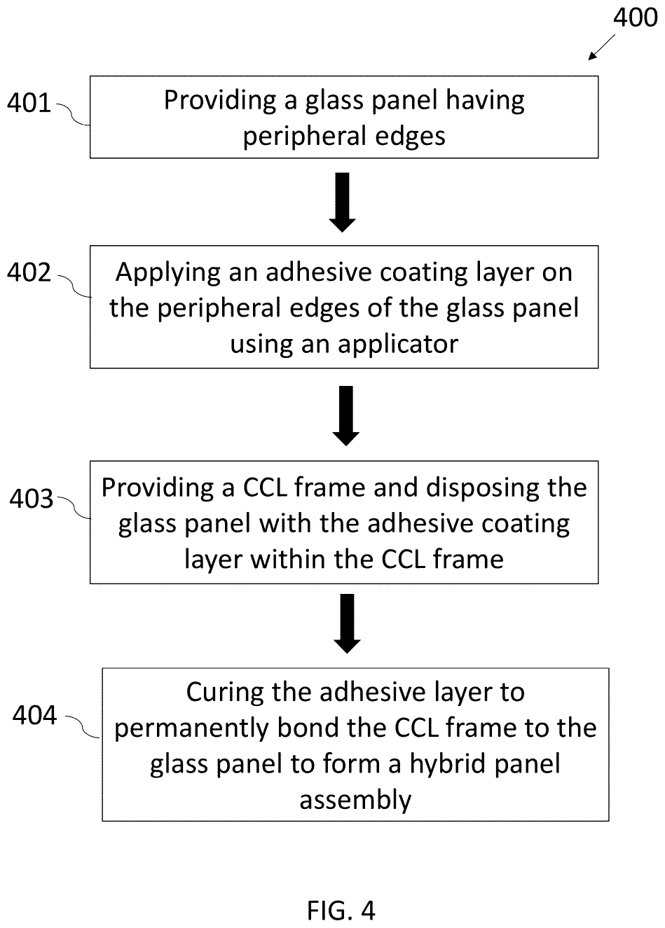

FIG. 4 shows a simplified flow diagram for an exemplary method for constructing a hybrid panel according to an aspect of the present disclosure.

The operation 401 may be directed to providing a glass panel having peripheral edges.

The operation 402 may be directed to applying an adhesive coating layer on the peripheral edges of the glass panel using an applicator.

The operation 403 may be directed to providing a CCL frame and disposing the glass panel with the adhesive coating layer within the CCL frame.

The operation 404 may be directed to curing the adhesive layer to permanently bond the CCL frame to the glass panel to form a hybrid panel assembly.

It will be understood that any property described herein for a particular hybrid semiconductor panel may also hold for any hybrid panel described herein. It will also be understood that any property described herein for a specific method for assembling such a hybrid panel may hold for any of the methods described herein. Furthermore, it will be understood that for any hybrid panel assembly and the methods described herein, not necessarily all the components or operations described will be shown in the accompanying drawings or method, but only some (not all) components or operations may be disclosed.

To more readily understand and put into practical effect the hybrid semiconductor panel assemblies having CCL frames, they will now be described by way of examples. For the sake of brevity, duplicate descriptions of features and properties may be omitted.

### Examples

Example 1 provides for a hybrid panel assembly including an edge coated glass panel, for which the edge coated glass panel includes a glass panel having peripheral edges and an adhesive coating layer deposited on the peripheral edges of the glass panel, for which the edge coated glass panel is a subcomponent for construction of the hybrid panel assembly.

Example 2 may include the hybrid panel of example 1 and/or any other example disclosed herein, which further includes a copper clad laminate (CCL) frame surrounding the glass panel, for which the adhesive coating layer bonds the CCL frame to the glass panel.

Example 3 may include the hybrid panel of example 1 and/or any other example disclosed herein, for which the adhesive coating layer includes an epoxy-based resin.

Example 4 may include the hybrid panel of example 1 and/or any other example disclosed herein, for which the adhesive coating layer has a thickness in a range of approximately 100 μm to 1 mm.

Example 5 may include the hybrid panel of example 1 and/or any other example disclosed herein, for which the glass panel is sized in a range of approximately 480×482 mm to 500×505 mm.

Example 6 may include the hybrid panel of example 2 and/or any other example disclosed herein, for which the glass panel with the CCL frame are together sized at approximately 510×515 mm.

Example 7 provides for a method that includes providing a glass panel having peripheral edges, and depositing an adhesive coating layer on the peripheral edges of the glass panel using an applicator to form an edge coated glass panel, for which the edge coated glass panel is a pre-built subcomponent for construction of a hybrid panel assembly.

Example 8 may include the method of example 7 and/or any other example disclosed herein, which further includes providing a CCL frame and disposing the edge coated glass panel within the CCL frame.

Example 9 may include the method of example 8 and/or any other example disclosed herein, for which providing the CCL frame further includes providing a support film attached to an underside of the CCL frame and removing the support film after the construction of the hybrid panel assembly is completed.

Example 10 may include the method of example 9 and/or any other example disclosed herein, for which the disposing the edge coated glass panel within the CCL frame further includes disposing the edge coated glass panel on the support film using a robotic arm.

Example 11 may include the method of example 8 and/or any other example disclosed herein, which further includes curing the adhesive coating layer to bond the CCL frame to the glass panel.

Example 12 may include the method of example 11 and/or any other example disclosed herein, for which curing the adhesive coating layer includes using an ultra-violet (UV) curing process.

Example 13 may include the method of example 11 and/or any other example disclosed herein, for which curing the adhesive coating layer includes using a thermal curing process.

Example 14 may include the method of example 12 and/or any other example disclosed herein, for which the UV curing process includes a UV source coupled to a processor that controls a polymerization pattern and rate.

Example 15 may include the method of example 11 and/or any other example disclosed herein, which further includes applying and curing the adhesive coating layer at an ambient temperature.

Example 16 may include the method of example 7 and/or any other example disclosed herein, for which the applicator includes a coating roller.

Example 17 may include the method of example 11 and/or any other example disclosed herein, which further includes performing a cleaning process to remove any contaminants from the hybrid panel assembly.

Example 18 provides for a hybrid panel assembly including an edge coated glass panel, for which the edge coated glass panel includes a glass panel having peripheral edges and an adhesive coating layer deposited on the peripheral edges of the glass panel, and is a subcomponent for a construction of the hybrid panel assembly, and a frame configured to surround the edge coated glass panel, for which the adhesive coating layer bonds the frame to the glass panel in the construction of the hybrid panel assembly.

Example 19 may include the hybrid panel of example 18 and/or any other example disclosed herein, for which the adhesive coating layer includes an epoxy-based resin.

Example 20 may include the hybrid panel of example 18 and/or any other example disclosed herein, for which the frame is made of a copper clad laminate.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A hybrid panel assembly comprising:
an edge coated glass panel, wherein the edge coated glass panel comprises:
a glass panel having peripheral edges and an adhesive coating layer deposited on the peripheral edges of the glass panel, wherein the edge coated glass panel is a subcomponent for a construction of the hybrid panel assembly.

2. The hybrid panel assembly of claim 1, further comprises a copper clad laminate (CCL) frame surrounding the glass panel, wherein the adhesive coating layer bonds the CCL frame to the glass panel.

3. The hybrid panel assembly of claim 1, wherein the adhesive coating layer comprises an epoxy-based resin.

4. The hybrid panel assembly of claim 1, wherein the adhesive coating layer has a thickness in a range of approximately 100 μm to 1 mm.

5. The hybrid panel assembly of claim 1, wherein the glass panel is sized in a range of approximately 480×482 mm to 500×505 mm.

6. The hybrid panel assembly of claim 2, wherein the glass panel with the CCL frame are together sized at approximately 510×515 mm.

7. A method comprising:
providing a glass panel having peripheral edges; and
depositing an adhesive coating layer on the peripheral edges of the glass panel using an applicator to form an edge coated glass panel, wherein the edge coated glass panel is a pre-built subcomponent for construction of a hybrid panel assembly.

8. The method of claim 7, further comprises providing a CCL frame and disposing the edge coated glass panel within the CCL frame.

9. The method of claim 8, wherein the providing the CCL frame further comprises providing a support film attached to an underside of the CCL frame and removing the support film after the construction of the hybrid panel assembly is completed.

10. The method of claim 9, wherein the disposing the edge coated glass panel within the CCL frame further comprises disposing the edge coated glass panel on the support film using a robotic arm.

11. The method of claim 8, further comprises curing the adhesive coating layer to bond the CCL frame to the glass panel.

12. The method of claim 11, wherein curing the adhesive coating layer comprises using an ultra-violet (UV) curing process.

13. The method of claim 11, wherein curing the adhesive coating layer comprises using a thermal curing process.

14. The method of claim 12, wherein the UV curing process comprises a UV source coupled to a processor that controls a polymerization pattern and rate.

15. The method of claim 11, further comprises applying and curing the adhesive coating layer at an ambient temperature.

16. The method of claim 7, wherein the applicator comprises a coating roller.

17. The method of claim 11, further comprises performing a cleaning process to remove any contaminants from the hybrid panel assembly.

18. A hybrid panel assembly comprising:
an edge coated glass panel, wherein the edge coated glass panel comprises:
a glass panel having peripheral edges and an adhesive coating layer deposited on the peripheral edges of the glass panel, and is a subcomponent for a construction of the hybrid panel assembly; and
a frame configured to surround the edge coated glass panel, wherein the adhesive coating layer bonds the frame to the glass panel in construction of the hybrid panel assembly.

19. The hybrid panel assembly of claim 18, wherein the adhesive coating layer comprises an epoxy-based resin.

20. The hybrid panel assembly of claim 18, wherein the frame is made of a copper clad laminate.
